(19) United States
(12) Patent Application Publication
(10) Pub. No.: US 2014/0062263 A1
(43) Pub. Date: Mar. 6, 2014

(54) PIEZOELECTRIC ACTUATOR UNIT

(71) Applicant: HONDA MOTOR CO., LTD., (US)

(72) Inventor: Kazuo Ogawa, Tochigi-ken (JP)

(73) Assignee: HONDA MOTOR CO., LTD., TOKYO (JP)

(21) Appl. No.: 13/833,344

(22) Filed: Mar. 15, 2013

(30) Foreign Application Priority Data
Apr. 6, 2012 (JP) 2012-087281

(51) Int. Cl. H01L 41/047; H01L 41/25

(52) U.S. Cl. CPC H01L 41/0477; H01L 41/25
USPC 310/364; 228/193

(57) ABSTRACT

A piezoelectric actuator unit includes a plurality of laminated piezoelectric elements, a first external electrode positioned on a first side surface of each piezoelectric element, and a conductive member connected to each first external electrode with a solder including indium, bismuth, or a mixture thereof, and some of the indium and/or bismuth in the solder is diffused into the soldered portions of the conductive member.

### CROSS REFERENCE TO RELATED APPLICATIONS

The present application claims priority under 35 U.S.C. §119 to Japanese Patent Application No. 2012-087281, filed Apr. 6, 2012, entitled “Piezoelectric Actuator Unit” the contents of which are incorporated herein by reference in their entirety.

### BACKGROUND

The present disclosure relates to a piezoelectric actuator unit. Piezoelectric actuators may, for example, be used to control a liquid flow control valve that is used in variable dampers, fuel injection devices, inkjet printers, and the like.

A known example of a piezoelectric actuator is a device that includes a piezoelectric element with alternately laminated internal electrodes made of conductive materials, and piezoelectric plates made of a piezoelectric material. Voltage is selectively applied via an external electrode connected to the internal electrodes to provide a desired displacement by extending or contracting the plates in the laminate or lamination direction. To increase the displacement of such a piezoelectric element, a plurality of piezoelectric elements have been bonded together on the surface in the laminate direction. For example, one or more inert layers may be laminated between adjacent piezoelectric elements to form the bond.

Furthermore, it is known to increase the insulation property of a piezoelectric actuator by providing a molded resin with electrical insulating properties on the outer perimeter surface of a piezoelectric element and also by covering the molded resin with a sleeve made of PPS, PET, 66 nylon, and the like.

However, there is a possibility of the molded resin or sleeve breaking due to heat exposure when the external electrode of the piezoelectric element is connected to a conductive member that extracts electric current therefrom. On the other hand, there is a possibility of a connection defect occurring due to an increase in temperature that occurs in the actuator-operating environment when the connection is made with a low melting point solder. Furthermore, when a large displacement is generated in an actuator that uses a ceramic piezoelectric material, deterioration in durability resulting from cracks occurring in the piezoelectric material due to interior stress of the piezoelectric material is a common concern.

### SUMMARY

In accordance with one embodiment, a piezoelectric actuator unit is provided that minimizes the occurrence of cracks in the piezoelectric material due to stress concentration during operation, suppresses breakage of the molded resin or sleeve due to heat, and maintains a good solder connection even as the temperature increases in the operating environment.

In accordance with one embodiment, a piezoelectric actuator unit is provided that includes a plurality of laminated piezoelectric elements, a first external electrode positioned on a first side surface of each piezoelectric element, and a conductive member connected to each first external electrode with a solder. The solder includes In, Bi, or a mixture thereof. Some of the In and/or Bi in the solder is diffused into the soldered portions of the conductive member.

In accordance with one embodiment, a piezoelectric actuator unit is provided that includes a first piezoelectric element including an external electrode, and a second piezoelectric element including an external electrode. The first and second piezoelectric elements are positioned with the external electrode of the first element positioned apart from the external electrode of the second element. A conductive member is connected to the external electrodes with a solder. The solder and the soldered portions of the conductive member include Bi, In, or a mixture thereof. The conductive member is configured to transfer stress away from the soldered portions of the conductive member.

In accordance with one embodiment, a method of making a piezoelectric actuator unit is provided. The method includes providing a first piezoelectric element including an external electrode, a second piezoelectric element including an external electrode, and a solder including Bi, In, or a mixture thereof; connecting a first part of the conductive member to the external electrode of the first element with the solder and diffusing some of the In and/or Bi in the first part; and connecting a second part of the conductive member to the external electrode of the second element with the solder and diffusing some of the In and/or Bi in the second part. In accordance with one embodiment, the solder provided includes 30.0 to 90.0 percent In by weight of the solder, 9.0 to 70 percent Sn by weight of the solder, 0.1 to 3.0 percent Ag by weight of the solder, and up to 0.5 percent Cu by weight of the solder. In accordance with one embodiment, the solder provided includes 50.0 to 60.0 percent Bi by weight of the solder, 37.0 to 50.0 percent Sn by weight of the solder, 1.0 to 2.5 percent Ag by weight of the solder, and 0.1 to 0.4 percent Cu by weight of the solder.

In accordance with one embodiment, a piezoelectric actuator unit of the present disclosure includes a plurality of piezoelectric elements laminated in the direction of voltage application, a holding member that houses the piezoelectric elements, an external electrode provided on a side surface of each piezoelectric element, and a conductive member that connects the external electrodes, wherein the conductive member and external electrodes are connected by a solder including a melting point reducing additive. The melting point reducing additive includes In, Bi, or a mixture thereof. Some of the melting point reducing additive is diffused from the solder to the soldered portions of the conductive member.

In accordance with one embodiment, the melting point of the solder is reduced because the solder contains a melting point reducing additive such as In, Bi, or a mixture thereof, to lower the heating temperature necessary to melt the solder used to connect the conductive member to the external electrodes. Therefore, the piezoelectric elements may be positioned in the holding member prior to connecting the conductive member to the external electrodes, as the heat required to melt the solder is reduced. Furthermore, some of the melting point reducing additive is diffused from the molten solder to the conductive member by heating. In other words, some of the melting point reducing additive contained in the solder is diffused in the conductive member due to contact between the conductive member and the molten solder. Accordingly, the melting point of the soldered portion of the conductive member is lowered and the melting point of the solder connecting the conductive member to the electrode is increased.

Without being limited to any particular theory, initial diffusion of the melting point reducing additive to the conductive member causes the surface of the conductive member to melt, and the diffusion of the melting point reducing additive advances farther inside the conductive member, causing melting to advance toward the interior of the conductive member. As a result, the conductive member has a gradient composition wherein the concentration of the melting point reducing additive decreases when transitioning from the surface to the interior of the conductive member. On the other hand, because the concentration of the melting point reducing additive decreases in the solder connecting the conductive member to the external electrodes, the melting point of the solder connecting the conductive member to the external electrodes is increased. Therefore, the anchoring strength of the solder connecting the conductive member to the external electrode is maintained even at higher temperatures in the assembly or operating environment, and thus the likelihood of separation of the conductive member from the external electrodes can be reduced.

In accordance with one embodiment, the solder can be a commercially available SnAgCu (tin-silver-copper) type solder containing flux (melting point: 200° C.). In a non-limiting example, the solder can be fabricated by mixing In, Bi, or a mixture thereof with a commercially available SnAgCu type solder containing flux at a predetermined ratio, and then melting and integrating both by heating at approximately 200° C. In another non-limiting example, SnAgCu type solder can be fabricated by adding In, Bi, or a mixture thereof to commercially available lead-free solder such as solder with a composition as specified by JIS Z3282 of Sn: 96.5%, Ag: 3%, and Cu: 0.5% and a melting point of 219° C., or with a composition of Sn: 99%, Cu: 0.7%, and Ag: 0.3% and a melting point of 219° C.

For example, solder with a melting point of 125° C. can be fabricated by melting In and solder with a composition as specified in JIS Z3282 at a 1:1 ratio. In another non-limiting example, solder can be fabricated by adding Bi to a Sn solder. For solder fabrication, the desired solder can be obtained by simply combining the materials and melting with heat. Examples of other solders that can be used include, but are not limited to, lead-tin alloy (PbSn, melting point: 200° C.), tin-silver alloy (SnAg, melting point: 215° C.), tin-antimony alloy (SnSb, melting point: 220° C.), and the like. Because solder containing In and/or Bi such as those solders described above can be fabricated to melt at a temperature of 140° C. or less for example, breakage of the holding member due to heat can be suppressed by appropriately selecting the material of the holding member when connecting the conductive member and external electrode of the piezoelectric element.

In accordance with one embodiment, the amount of In and/or Bi included in the solder is 30 to 60 weight % by weight of solder. If the amount of In and/or Bi that is contained is 30 weight % or higher by weight of solder, the conductive member can be securely connected to the external electrodes at temperatures of about 140° C. or higher where heat resistant resins will not thermally deform. Furthermore, if the amount of In and/or Bi that is contained is 60 weight % or less by weight of solder, the connection can be securely made at a temperature sufficiently lower than the 271° C. melting point of Bi alone, such as 140° C. or lower for example. In a non-limiting example, the amount of In and/or Bi contained in the solder is in the range of 40 to 45 weight % by weight of solder.

In accordance with one embodiment, a conductive member uses the same solder base material to which In and/or Bi has not been added. For example, if the same material as the solder base material of commercially available wire solder is used for the conductive member, the procurement cost can be reduced, the wettability with the solder will be favorable, and the bonding strength can be increased.

In accordance with one embodiment, the piezoelectric elements can feature a configuration wherein a plurality of interior electrodes made of a conductive material, and a plurality of piezoelectric plates made of piezoelectric material such as ceramic, and the like are alternately laminated. The interior electrodes are exposed on a side surface of the piezoelectric element, and an external electrode is bonded to that side surface so that the external electrode is connected to at least some of the internal electrodes. The piezoelectric material can be a known piezoelectric material. In a non-limiting example, the piezoelectric material is barium titanate or potassium niobate. Furthermore, the external electrode can be configured by plating a metal or metal alloy, such as Sn and the like, onto the side surface of the piezoelectric element. A second external electrode may be bonded to another side surface of the piezoelectric element, and connected to the internal electrodes that are not connected to the first external electrode.

In accordance with one embodiment, the piezoelectric elements are housed in the holding member without mutually contacting and are prevented from moving in the direction orthogonal to the laminated direction by the holding member.

In a configuration where piezoelectric elements are mutually joined on the surface in the laminate direction, the interior stress of the individual piezoelectric elements are combined, and when a force is added in the laminate direction, the combined stress acts in the direction orthogonal to the laminate direction, and the piezoelectric actuator unit is deformed, for example, by buckling. Furthermore, cracks can occur in the piezoelectric elements due to the combined stress. In accordance with one embodiment, the displacement or load in the horizontal direction that is applied to the piezoelectric elements can be dispersed because the piezoelectric elements are not bonded on the surface in the laminate direction, so buckling and cracks are suppressed and reliability can be improved.

In accordance with one embodiment, the conductive member is configured to absorb stress or otherwise transfer stress away from the soldered connection between the conductive member and the external electrodes. In an illustrative example, the conductive member bends or curves between adjacent piezoelectric elements. Accordingly, when a piezoelectric element expands or contracts in the laminate direction, the conductive member deforms and conforms at the curved section or bent section, to relieve the stress concentrated towards the soldered connections. Therefore, breakage due to degradation over time of those connections can be suppressed. In a non-limiting example, the conductive member can be a string shaped member wherein fine wires made of solder material are braided together. Because the braided conductive member can extend and contract, it can track the expansion or contraction of one or more of the piezoelectric elements to reduce stress to the soldered connections and the piezoelectric elements.

In accordance with one embodiment, a melting point reducing additive is included in a solder to reduce the heating temperature required to connect the conductive member and the external electrode, and therefore suppress breakage of the holding member due to heat exposure during assembly of the piezoelectric actuator unit. Furthermore, because the melting point of the solder connecting the external electrode to the conductive member increases as the melting point reducing additive diffuses into the conductive member, the anchoring strength of the solder connecting the conductive member to the external electrode is maintained even at temperatures in the operating environment exceeding the original melting point of the solder, and thus the likelihood of the conductive member disconnecting from the external electrode can be reduced.

### BRIEF DESCRIPTION OF THE DRAWINGS

FIG. 1A is a side surface view illustrating part of a piezoelectric actuator unit in accordance with one embodiment of the present disclosure.

FIG. 1B is a side view illustrating a part of a holding member removed from the piezoelectric actuator unit shown in FIG. 1A.

FIG. 1C is a side view of a plurality of plungers and piezoelectric elements removed from the piezoelectric actuator unit shown in FIG. 1A.

FIG. 2A is a portion of a view of FIG. 1B in the direction of arrow A enlarged for magnification purposes.

FIG. 2B is a portion of a view B of FIG. 1B enlarged for magnification purposes.

FIG. 2C is a portion of a view C of FIG. 1B enlarged for magnification purposes.

FIG. 3 is a cross section of a piezoelectric actuator unit in accordance with one embodiment of the present disclosure.

FIG. 4 is a side view of a piezoelectric element in accordance with one embodiment of the present disclosure.

FIG. 5 is a side cross section view of the piezoelectric element shown in FIG. 4.

FIG. 6A is a side view of a conductive member in accordance with one embodiment of the present disclosure.

FIG. 6B is a side view of the conductive member shown in FIG. 6A connected to a plurality of piezoelectric elements in accordance with one embodiment of the present disclosure.

FIG. 7A is a side cross section view illustrating a base part of a solder connected to an external electrode in accordance with one embodiment of the present disclosure.

FIG. 7B is a side cross section view illustrating a conductive member connected to the external electrode of FIG. 7A in accordance with one embodiment of the present disclosure.

FIG. 7C is a side cross section view illustrating the diffused state of a melting point reducing additive in the conductive member shown in FIG. 7B in accordance with one embodiment of the present disclosure.

FIG. 8 is a horizontal cross section view a piezoelectric actuator unit before installing a conductive member to the piezoelectric elements in accordance with one embodiment of the present disclosure.

FIG. 9 shows the piezoelectric actuator of FIG. 8 after connecting a first conductive member to the piezoelectric elements in accordance with one embodiment of the present disclosure.

FIG. 10 shows the piezoelectric actuator unit of FIG. 9 after connecting a second conductive member to the piezoelectric elements in accordance with one embodiment of the present disclosure.

FIG. 11A is a side view illustrating the state where a lateral load acts on a piezoelectric actuator unit including piezoelectric elements that intersect at right angles.

FIG. 11B is a side view illustrating the state where a lateral load acts on the piezoelectric actuator unit in accordance with one embodiment of the present disclosure.

FIG. 12A is a side view illustrating an example of a conductive member made of braided wire in accordance with one embodiment of the present invention.

FIG. 12B is a side view illustrating an example of a curved conductive member in accordance with one embodiment of the present invention.

FIG. 13A is a scanning electron microscope (SEM) image of a soldered portion of a conductive member, where a solder including Indium as a melting point reducing additive was used.

FIG. 13B is an Energy-dispersive X-ray (EDX) element map of Indium in the soldered portion of the conductive member of FIG. 13A that shows the state of Indium diffused in the soldered portion of the conductive member.

FIG. 13C is an Energy-dispersive X-ray (EDX) element map of Tin in the soldered portion of the conductive member of FIG. 13A that shows the state of Tin diffused in the soldered portion of the conductive member.

### DETAILED DESCRIPTION

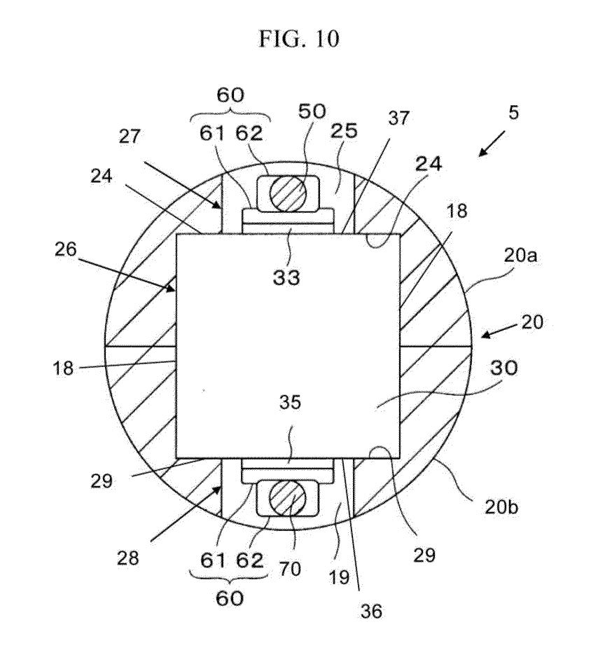

Referring to FIG. 10, a piezoelectric actuator unit 5 is provided in accordance with one embodiment of the present disclosure. The piezoelectric actuator unit 5 includes a plurality of piezoelectric elements 30 positioned in a holding member 20. Each piezoelectric element 30 includes an external electrode 33. A conductive member 50 is connected to the external electrodes 33 with a solder 60. The solder 60 optionally includes a melting point reducing additive.

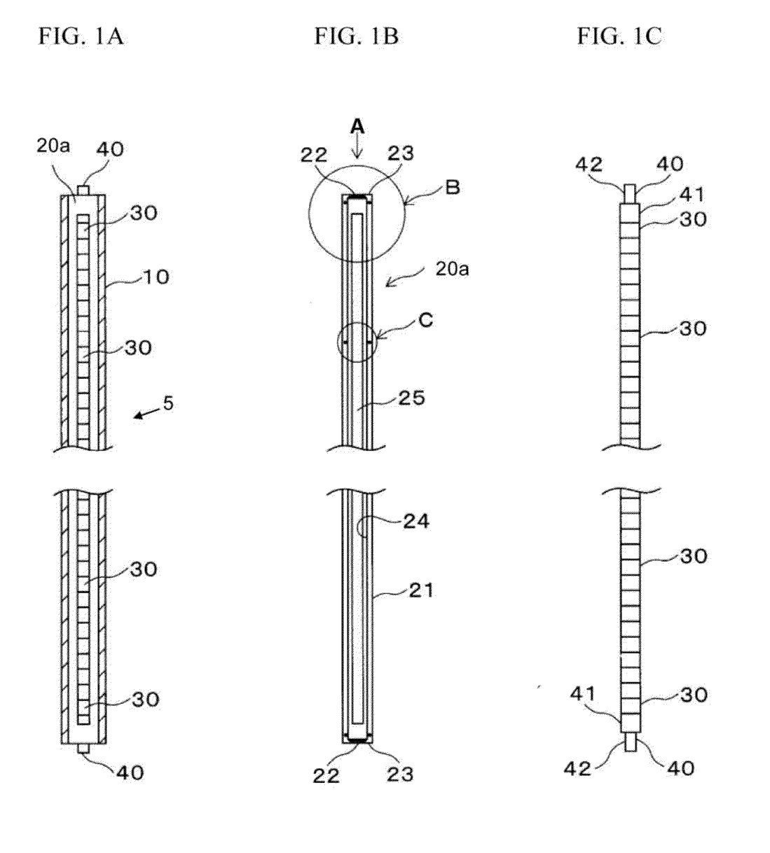

Referring to FIG. 1A, the piezoelectric actuator unit 5 may be provided with a housing 10 that includes openings on both ends. The housing 10 has a cylindrical shape and is made of a metal, although other shapes and materials may be used. A portion of the housing 10 and the holding member 20 positioned therein is not shown in FIG. 1A for purposes of describing the interior of the piezoelectric actuator unit 5 in accordance with one embodiment of the present disclosure.

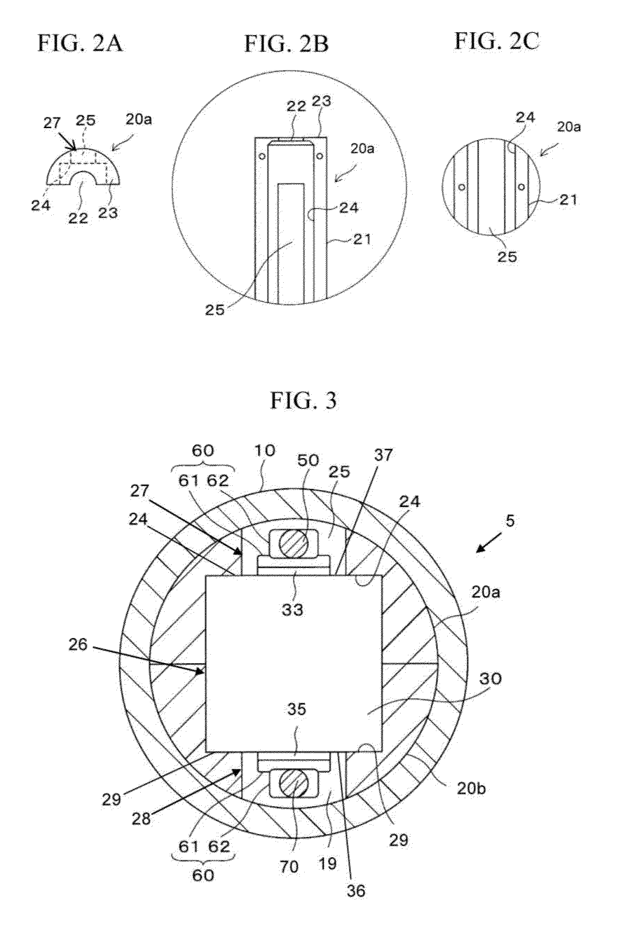

As shown in FIG. 1A, a first part 20a of the holding member 20 is positioned inside the housing 10. As shown in FIGS. 1B, 2A, 2B, and 2C, the first part 20a has an elongated, semi-cylindrical shaped body 21 that terminates with lid part 23 formed on both ends of the body 21 that include an opening 22 in a center part. As shown in FIG. 3, the holding member 20 also includes a second part 20b that has an elongated, semi-cylindrical shape. However, it is to be understood that the holding member 20 is not limited to such a two-part configuration and may comprise a single integral configuration, or may be formed from more than one or two parts. It is also to be understood that although the holding member 20 is shown herein as cylindrically shaped, the present disclosure is not limited to such, and the holding member 20 may be provided in a variety of shapes.

As shown FIG. 10, the holding member 20 defines a first chamber 26 and a second chamber 27 therein. A pair of shoulders 24 is provided in the holding member 20 that extend the length of the first chamber 26 and the second chamber 27. Furthermore, the second chamber 27 is provided with an opening 25 that extends in the longitudinal direction of the holding member 20 to provide access to the second chamber 27 from the exterior of the holding member 20. The holding member 20 is made of a polymeric material including, but not limited to, a synthetic plastic such as PP (polypropylene), PPS (polyphenylene sulfide), PA (polyamide), PBT (polybutylene terephthalate), and the like. The holding member 20 may have high temperature rigidity so that it will not deform even if heated at temperatures up to 140° C.

As shown in FIG. 10, the holding member 20 may be provided with a third chamber 28. A pair of shoulders 29 is provided in the holding member 20 that extend the length of the first chamber 26 and the third chamber 28. Furthermore, the third chamber 28 is provided with an opening 19 that extends in the longitudinal direction of the holding member 20 to provide access to the third chamber 28 from the exterior of the holding member 20.

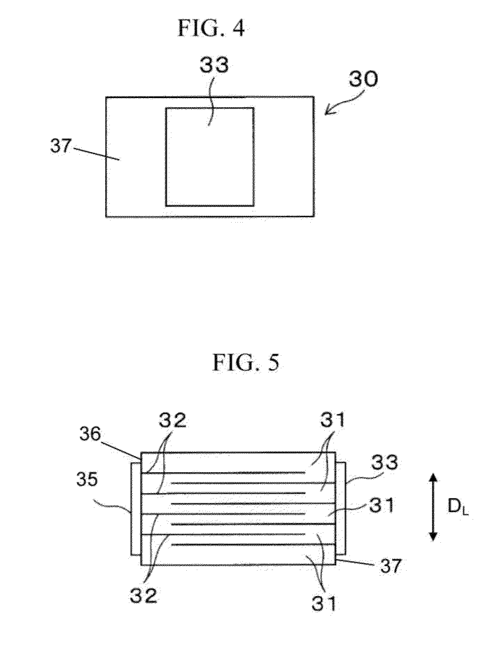

As shown in FIGS. 1A and 10, the piezoelectric elements 30 are positioned in the first chamber 26 of the holding member 20. As shown in FIG. 5, the piezoelectric elements 30 include a plurality of piezoelectric plates 31 made of a piezoelectric material including, but not limited to, barium titanate and potassium niobate, and a plurality of interior (or internal) electrodes 32 made of a conductive material. The piezoelectric elements 30 are formed by alternatively stacking, layering, or laminating the piezoelectric plates 31 and the interior electrodes 32. Although shown in FIGS. 4 and 5 as having a substantially square or rectangular shape, the piezoelectric elements 30 are not limited to such and may have a variety of different shapes.

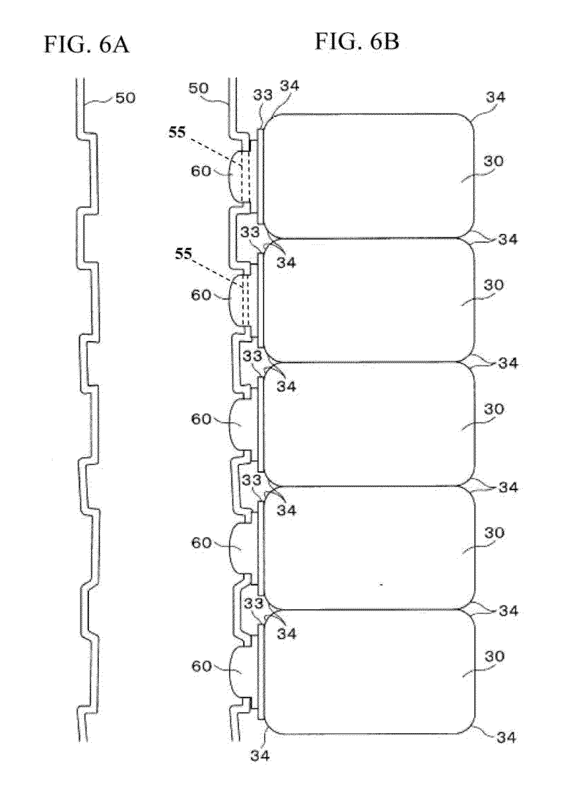

The piezoelectric elements 30 may be barrel polished, and may be provided with a beveled part 34 with a cross section arc shape on the corner parts, as illustrated in FIG. 6B. As shown in FIGS. 4 and 5, the external electrode 33 is provided on a side surface 37 of the piezoelectric plates 31, and is connected to at least some of the interior electrodes 32. A second external electrode 35 is provided that is positioned on a second side surface 36 of the piezoelectric plates 31, and is connected to the interior electrodes 32 that are not connected to the first external electrode 33. The external electrodes 33, 35 may be formed with Sn plating and the like in a non-limiting example. The Sn plating can be formed by either electroplating or electroless plating.

In accordance with one embodiment, the piezoelectric elements 30 are not bonded together. In a non-limiting example, at least one piezoelectric element 30 is not directly bonded in any way to another piezoelectric element 30 in the first chamber 26. In another non-limiting example, none of the piezoelectric elements 30 are bonded directly in any way to another piezoelectric element 30 in the first chamber 26. As such, the holding member 20 may be configured to position the piezoelectric elements 30 therein in a state where movement is prevented in the direction orthogonal to the lamination direction D_{L} (as shown in FIG. 5) of the piezoelectric elements 30 by the shoulders 24, the shoulders 29, and one or more walls 18 (as shown in FIG. 10). For example, the shoulders 24, the shoulders 29, and the walls 18 engage the piezoelectric elements 30 to guide movement of the piezoelectric elements 30 in the first chamber 26 in the lamination direction D_{L} along the length of the holding member 20. As shown in FIGS. 1A and 1C, a plunger 40 is positioned adjacent to the piezoelectric elements 30 located on both ends. The plunger 40 is made of stainless steel for example, and may include a base part 41 with the same planar view shape as the piezoelectric element 30, and a column shaped pin 42 standing on the base part 41. Thus, the pin 42 protrudes from the opening 22 of the holding member 20 and the housing 10 as shown in FIG. 1A.

As shown in FIGS. 6A and 6B, the conductive member 50 is connected to each external electrode 33 with the solder 60. The conductive member 50 may be a wire made of solder materials including, but not limited to, SnAgCu and the like. As shown in FIG. 6A, the conductive member 50 may be bent in a zigzag shape. As shown in FIG. 6B, the pitch of the bend may conform to the pitch of the piezoelectric element 30, and the conductive member 50 is connected to the external electrodes 33 by the solder 60 at positions that are bent to the piezoelectric element 30 side. Although the conductive member 50 is shown to be one continuous piece, the conductive member 50 connected to the electrodes 33 may be comprised of a plurality of pieces that may or may not be directly connected to each other.

As shown in FIG. 3, a second conductive member 70 is connected to each second external electrode 35 with the solder 60. The conductive member 70 may also be a wire made of solder materials including, but not limited to, SnAgCu and the like. The conductive member 70 may also be bent in a zigzag shape. The pitch of the bend may conform to the pitch of the piezoelectric element 30, and the conductive member 70 may be connected to the external electrodes 35 by the solder 60 at positions that are bent to the piezoelectric element 30 side. Although the conductive member 70 may be one continuous piece that is connected to each second external electrode 35, or the conductive member 70 may be comprised of a plurality of pieces that may or may not be directly connected to each other.

In accordance with one embodiment of the present disclosure, the solder material used to form the solder 60 includes a melting point reducing additive. The melting point reducing additive is Bi, In, or a mixture thereof. In a non-limiting example, the melting point reducing additive is present in an amount of 30 to 60 weight % by weight of the solder. In an illustrative example, the solder material used to form the solder 60 includes 30 to 60 weight % of In, in a solder material such as SnAgCu and the like containing flux. In an illustrative example, the solder material used to form the solder 60 includes 30 to 60 weight % of Bi, in a solder material such as SnAgCu and the like containing flux. In yet another illustrative example, the solder material used to form the solder 60 includes 30 to 60 weight % of a mixture of Bi and In, in a solder material such as SnAgCu and the like containing flux.

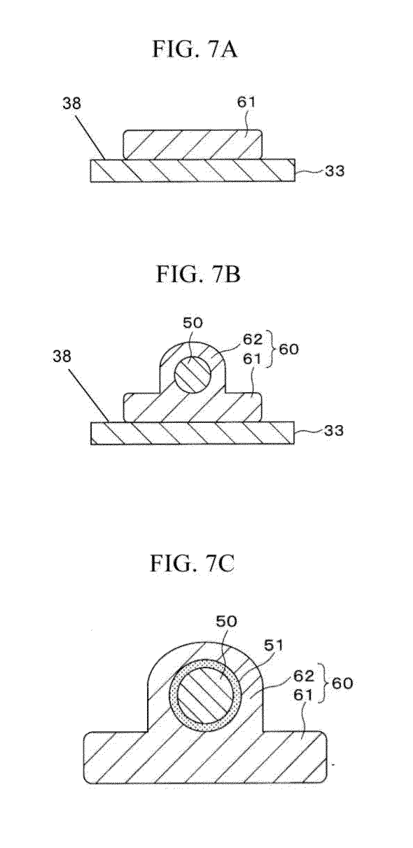

As shown in FIGS. 7A, 7B, and 7C, the solder 60 connecting the conductive member 50 to the external electrodes 33 includes a part 62 that covers a portion 55 of the conductive member 50 (best shown in FIG. 6B and hereinafter referred to “the soldered portion 55”). The part 62 may be directly positioned on a surface 38 of the external electrode 33. Optionally, the solder 60 includes a base part 61 that is positioned on the surface 38 between the part 62 and the external electrode 33. As shown in FIG. 7B, the part 62 may be a convex shape that rises up from the base part 61 to cover at least part of the conductive member 50. Although the solder 60 is shown as encapsulating the conductive member 50 (soldered portion 55) adjacent the external electrode 33, it is to be understood that the solder 60 does not have to encapsulate the conductive member 50 adjacent the external electrode 33 to connect the conductive member 50 to the external electrode 33.

The solder material forming the base part 61 may be a different metal or metal alloy than the solder material forming the part 62. In an illustrative example, the base part 61 is Sn, and the part 62 is a SnAgCu alloy. It is to be also to be understood that either, both, or neither of the base part 61 and the part 62 may be formed from a solder material that includes the melting point reducing additive. In an illustrative example, the base part 61 is formed with a solder material that does not contain the melting point reducing additive, and the part 62 is formed with a solder material that includes the melting point reducing additive. In an illustrative example, the base part 61 and the part 62 are formed with a solder material that includes the melting point reducing additive, and at least some of the melting point reducing additive diffuses from the base part 61 to the conductive member 50. Although not shown in FIG. 7C, it is to be understood that some of the melting point reducing additive may diffuse from the solder material used to form the part 62 into the base part 61.

A method for manufacturing the piezoelectric actuator unit 5 in accordance with one embodiment of the present disclosure is provided. Sn is plated onto the side surface 37 to form the external electrodes 33 (as shown in FIG. 5) where the interior electrodes 32 of the piezoelectric elements 30 are exposed to electrically connect the interior electrodes 32 and the external electrodes 33 of each piezoelectric element. Optionally, the solder material that forms the base part 61 of the solder 60 is heated to 200° C., for example, and applied to form the base part 61 on the surface 38 of the external electrode 33 (Refer to FIG. 7A).

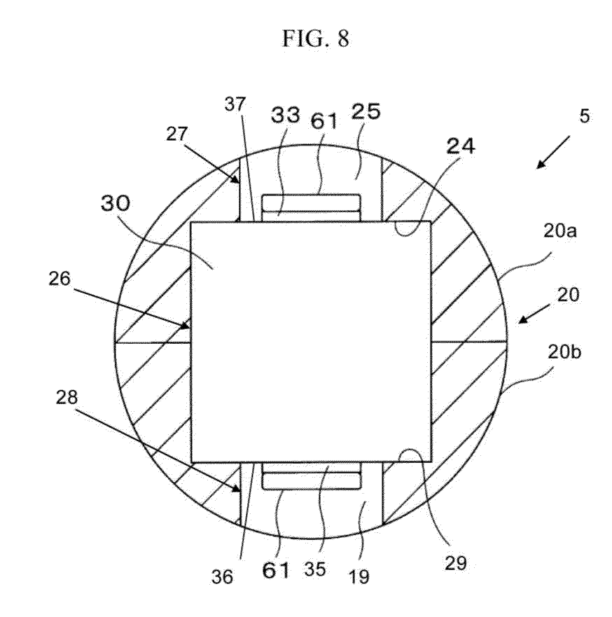

The piezoelectric elements 30 and the plungers 40 are positioned in the first chamber 26 of the holding member 20. For example, the piezoelectric elements 30 and the plungers 40 may be positioned in the first part 20a by applying preliminary pressure in the laminate direction D_{L} to compress the piezoelectric elements 30 and/or the plungers 40. In a non-limiting example, the piezoelectric elements 30 and the plungers 40 are inserted into the first part 20a with the external electrodes 33 positioned in the second chamber 27 with the surface 38 facing towards the opening 25. Next (as shown in FIG. 8), the piezoelectric elements 30 and plungers 40 are fit into the second part 20b with the second external electrodes 35 positioned in the third chamber 28 with the surface of the second external electrodes 35 facing towards the opening 19. Although not shown, it is understood that the first part 20a can be secured to the second part 20b, for example, with ultrasonic welding, with an adhesive, with fasteners, or any combination thereof.

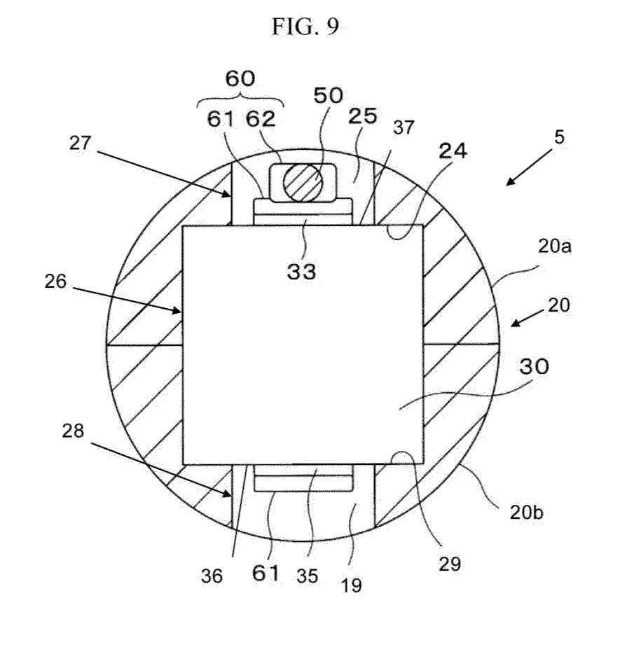

As shown in FIG. 9, the conductive member 50 is positioned in the second chamber 27 on the base part 61, and is connected to the external electrode 33 with the convex part 62 that is formed by soldering with solder material. The solder material optionally contains the melting point reducing additive and has a melting point of 140° C., for example. In an illustrative example, the solder material contains 50 weight % In by weight of the solder material, and the melting point is 125° C., and the holding member 20 is a plastic material having an operating temperature of at least 125° C., and thus soldering is possible at a temperature that does not cause deformation or breakage of the holding member 20. In a non-limiting example, the operating temperature for the material used to make the holding member 20 is higher than the melting point of the solder containing the melting point reducing additive, and the operating temperature is one of the melting point temperature, glass transition temperature, heat deflection temperature, or Vicat softening temperature of the material used to make the holding member 20.

As shown in FIG. 7C, when the solder material that is melted contacts the conductive member 50, the melting point reducing additive (in this example In) that is contained in the solder material diffuses into the conductive member 50, and the surface part 51 of the conductive member 50 melts. Thereby, the conductive member 50 and the solder 60 bond together, and a reliable electrical connection is made.

Due to the diffusion of In from the solder 60 into the soldered portion 55 of the conductive member 50 (shown in FIG. 6B), the interface between the part 62 and the outer surface of the soldered portion 55 of the conductive member 50 disappears, and the melting point of the solder 60 (at least of the part 62) increases to 180° C. for example, because the concentration of In in the solder 60 (at least of the part 62) is reduced as it diffuses into the soldered portion 55 of the conductive member 50. Therefore, the anchoring strength of the solder 60 is maintained even at operating temperatures higher than the original melting point of the soldering material (125° C. in this example), and thus separation of the conductive member 50 can be prevented. On the other hand, the melting point of the soldered portion 55 of the conductive member 50 is reduced from 219° C. to about 180° C. for this example because the In is diffused to form a gradient composition in the soldered portion 55 of the conductive member 50. Therefore, the part 62 and the soldered portion 55 of the conductive member 50 do not thermally deform or melt during connection of the other parts of the conductive member 50 to the other external electrodes 33 with the solder material having a melting point of 125° C.

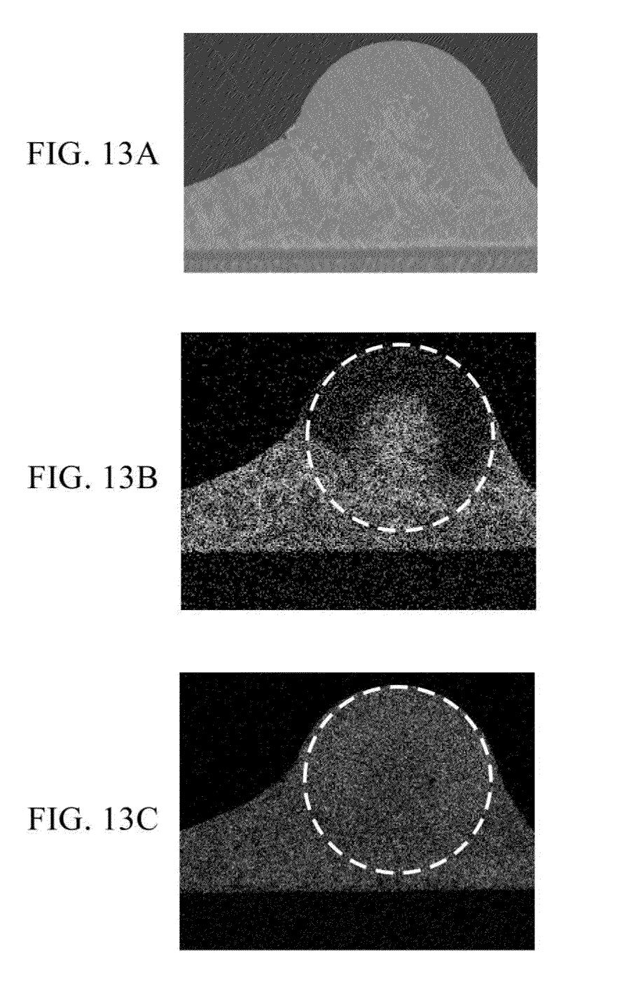

FIG. 13A is a scanning electron microscopy (SEM) image of the cross section of the connection of the external electrode 33 with the conductive member 50 soldered as described above. FIG. 13B is an Energy-dispersive X-ray (EDX) element map of In of the same cross section shown in FIG. 13A with a dotted line overlaying the element map to show the original shape of the conductive member 50 before soldering. FIG. 13C is an EDX element map of Sn in the same cross section shown in FIG. 13A with a dotted line overlaying the element map to show the original shape of the conductive member 50 before soldering. In this case, commercially available SnAgCu solder material containing flux (produced by Senju Metal Industry Co., Ltd., M705, Sn: 96.5 mass %, Ag: 3 mass %, and Cu: 0.5 mass %) was applied to the external electrode 33 at 200° C. to form the base part 61. A different solder material was fabricated by mixing and melting the commercially available SnAgCu solder material containing flux (produced by Senju Metal Industry Co., Ltd., M705, Sn: 96.5 mass %, Ag: 3 mass %, and Cu: 0.5 mass %) and In (produced by Kanto Chemical Co., Inc., Cat. 20018-32) at a 1:1 mass ratio. Furthermore, commercially available SnAgCu wire solder was selected as the conductive member 50 and positioned on to the base part 61 described above and soldered thereon with the solder material containing the In at a temperature of 140° C. to form the part 62.

As can be seen from FIG. 13B, In did not exist in the originally unsoldered conductive member 50, but during soldering the In is diffused from the solder to the conductive member 50 by soldering at 140° C. Furthermore, both an elemental analysis shown in FIG. 13B and the structural observation shown in 13A indicate that the conductive member 50 and the solder are integrated without an interface. As can be seen from FIG. 13C, Sn is present throughout both the solder and the conductive member 50.

As shown in FIG. 10, the second conductive member 70 is mounted on top of the base part 61 that is positioned on the second external electrode 35, upon which the convex part 62 is formed by soldering with solder material that has been melted at 140° C. The holding member 20 may then be inserted into the housing 10 as shown in FIG. 3.

As described above, the convex part 62 and the base part 61 of the solder 60 are melted separately. However, it is also possible to apply both in the same step. In a non-limiting example, it is possible to apply a powdered solder material that forms the base part 61 on top of the external electrode 33, and to then mount the conductive member 50 thereon, apply the solder material that forms the convex part 62 thereon, and heat treat at 140° C. in a heating furnace. In this case, heat treatment is performed twice, but the melting point of the solder 60 and the soldered portion 55 of the conductive member 50 following the first heat treatment was changed to about 180° C., so the solder 60 and the soldered portion 55 of the conductive member 50 will not melt during a second heat treatment process. For example, the solder 60 and the soldered portion 55 of the conductive member 50 will not melt during a second heat treatment process at 140° C. that is used to mount the second conductive member 70 to the second external electrode 35. In another illustrative example, the solder 60 and the soldered portion 55 of the conductive member 50 will not melt during a second heat treatment process used to increase diffusion of the melting point reducing additive into the conductive member 50.

In the piezoelectric actuator unit 5, a potential difference occurs between the interior electrodes 32 due to the application of voltage from an external power source (not shown) to the conductive members 50, 70 so that the piezoelectric elements 30 expand in the laminate direction D_{L} along the length of the holding member 20. Thus, the plunger 40 is operated by moving the predetermined location of the fuel injection device and the like for example. Deformation or breakage of the holding member 20 due to heat exposure during assembly of the piezoelectric actuator unit 5 can be prevented (or at least the likelihood is reduced) by including the melting point reducing additive in the solder, because the heating temperature when connecting the conductive member 50 and the external electrode 33 (and optionally the second conductive member 70 and the second external electrode 35) with the solder can be reduced; furthermore, the anchoring strength of the solder 60 is maintained even at higher temperatures in the operating environment because the melting point of the solder 60 (or at least the solder 62) increases, and thus the durability of the connection between the conductive member 50 and the external electrode 33 (and optionally the second conductive member 70 and the second external electrode 35) is improved.

In one embodiment, the conductive member 50 (and optionally the second conductive member 70) is configured, so that when one or more of the piezoelectric elements 30 expand or contract in the laminate direction D_{L}, the conductive member 50 deforms and conforms at the bent section, and the stress concentration in the soldered area is alleviated, and thus breakage of the connection between the external electrode 33 and the conductive member 50 due to degradation over time of those areas can be suppressed. Furthermore, the material of the conductive member 50 (and optionally the second conductive member 70) may be the same as the base material that is combined with the melting point reducing additive to form the solder 60 (at least the same as the part 62), so the procurement cost can be reduced, the wettability of the solder 60 and the conductive member 50 will be favorable, and the anchoring strength of both can be increased.

In the embodiment mentioned above, the displacement or load in the horizontal direction applied to the piezoelectric actuator unit 5 can be dispersed because the piezoelectric elements 30 are not bonded together, and thus buckling and cracks are suppressed, and reliability can be improved.

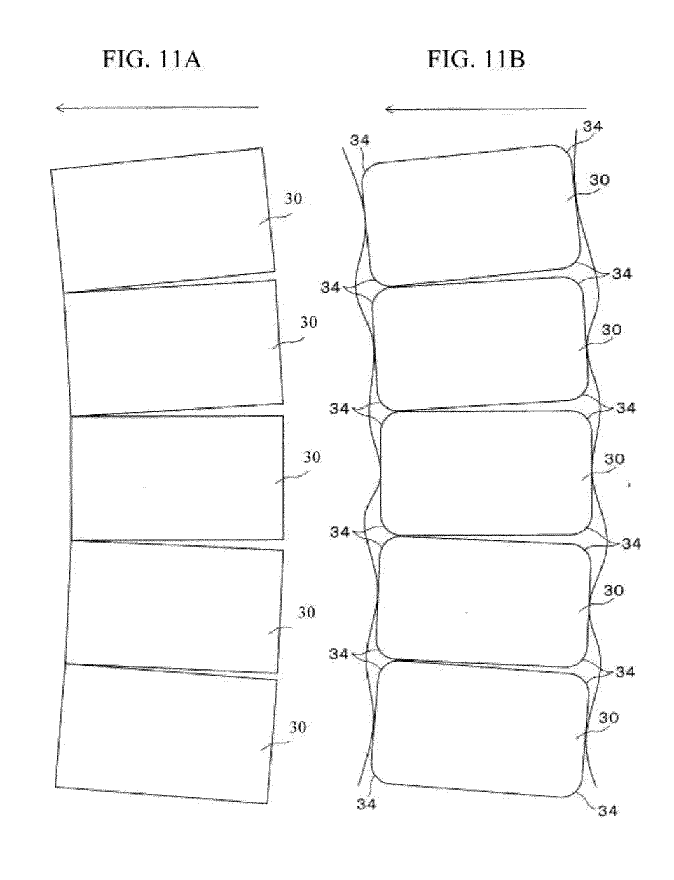

Furthermore, as illustrated in FIG. 11A, with a configuration where the corner parts of the piezoelectric elements 30 intersect at right angles, when stress in the lateral direction is applied during operation, the corner parts contact each other at a point, and the stress becomes concentrated, leading to defects such as cracking and the like. Accordingly, barrel polishing or other processing may be performed on the piezoelectric element 30 to form a beveled part 34 at the corner parts, and as a result, the piezoelectric elements 30 contact each other on a plane even when stress is applied in the lateral direction, and thus stress concentration can be alleviated.

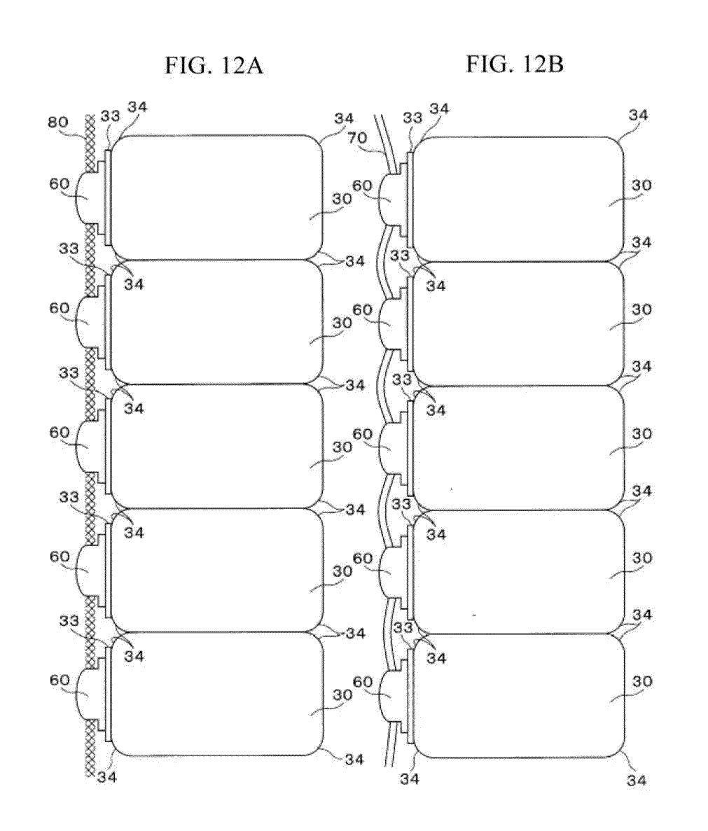

FIGS. 6A, 6B, 12A, and 12B illustrate nonlimiting examples of the conductive member 50. The conductive member 50 may be curved, bent, coiled, or otherwise configured so that the length of the conductive member 50 between the soldered portions 55 of the conductive member 50 is longer than the distance between the soldered portions 55 of the conductive member 50. As shown in FIG. 6B, the soldered surfaces of the external electrodes 33 are positioned in coplanar alignment and at least a part of the conductive member 50 between the soldered portions 55 extends away from the plane. As shown in FIG. 12B, the conductive member 50 may be bent in a wavelike manner. The conductive member 50 deforms and conforms at the curved section between the soldered portions 55 of the conductive member 50, so that the concentration of stress in the solder 60 is alleviated, and breakage due to degradation over time of those areas can be suppressed. Furthermore, the example illustrated in FIG. 12A uses a conductive member 50 in the form of a braided wire where fine wires made of solder material are braided together. Accordingly, the conductive member in FIG. 12A can extend and contract as the piezoelectric elements 30 expand and contract in the lamination direction D_{L}.

The present disclosure can be used, but is not limited to, to control a liquid flow rate control valve used in attenuating force variable dampers, fuel injection devices, inkjet printers, and the like.

The foregoing description of embodiments and examples has been presented for purposes of illustration and description. It is not intended to be exhaustive or limiting to the forms described. Numerous modifications are possible in light of the above teachings. Some of those modifications have been discussed and others will be understood by those skilled in the art. The embodiments were chosen and described for illustration of various embodiments. The scope is, of course, not limited to the examples or embodiments set forth herein, but can be employed in any number of applications and equivalent devices by those of ordinary skill in the art. Rather it is hereby intended the scope be defined by the claims appended hereto.

What is claimed is:

1. A piezoelectric actuator unit comprising:
a plurality of laminated piezoelectric elements;
a first external electrode positioned on a first side surface of each piezoelectric element; and
a conductive member connected to each first external electrode with a solder including indium, bismuth, or a mixture thereof, and some of the indium and/or bismuth in the solder is diffused into the soldered portions of the conductive member.

2. The piezoelectric actuator unit according to claim 1, further comprising a holding member, wherein the piezoelectric elements are positioned in the holding member without the external electrodes mutually contacting and the holding member is configured to prevent the piezoelectric elements from moving in a direction orthogonal to the lamination direction of the piezoelectric elements.

3. The piezoelectric actuator unit according to claim 1, further comprising a holding member, wherein the holding member defines a first chamber and a second chamber therein, and the piezoelectric elements are positioned in the first chamber and the conductive member and each first external electrode of the piezoelectric elements are positioned in the second chamber with the first external electrodes positioned apart from each other, wherein the holding member includes an elongated opening to the second chamber to provide access to each first external electrode and the conductive member from the exterior of the holding member.

4. The piezoelectric actuator unit according to claim 3, further comprising a second external electrode positioned on a second side surface of each piezoelectric element, and a second conductive member connected to each second external electrode with a solder including indium, bismuth, or a mixture thereof, and some of the indium and/or bismuth in the solder is diffused into the soldered portions of the second conductive member, wherein the holding member includes a third chamber, wherein the second conductive member and each second external electrode are positioned in the third chamber with the second external electrodes positioned apart from each other, and wherein the holding member includes a second elongated opening to the third chamber to provide access to each second external electrode and the second conductive member from the exterior of the holding member.

5. The piezoelectric actuator unit according to claim 1, further comprising a holding member, wherein the holding member defines a first chamber and a second chamber therein, and the piezoelectric members are positioned in the first chamber and the conductive member and each first external electrode of the piezoelectric elements are positioned in the second chamber with the first external electrodes positioned apart from each other, and wherein the holding member includes a pair of shoulders extending along the length of the first and the second chambers that are capable of engaging the first side surface of the piezoelectric elements to guide movement of the piezoelectric elements in the first chamber in the lamination direction of the piezoelectric elements.

6. The piezoelectric actuator unit according to claim 5, further comprising a second external electrode positioned on a second side surface of each piezoelectric element, and a second conductive member connected to each second external electrode with a solder including indium, bismuth, or a mixture thereof, and some of the indium and/or bismuth in the solder is diffused into the soldered portions of the second conductive member, wherein the holding member includes a third chamber, and wherein the second conductive member and each second external electrode are positioned in the third chamber with the second external electrodes positioned apart from each other.

7. The piezoelectric actuator unit according to claim 6, wherein the holding member includes a second pair of shoulders extending along the length of the first and the third chambers that are capable of engaging the second side surface of the piezoelectric elements to guide movement of the piezoelectric elements in the lamination direction of the piezoelectric elements.

8. The piezoelectric actuator unit according to claim 1, wherein the solder includes a metal or metal alloy in addition to indium, bismuth, or a mixture thereof, and the conductive member is made of the metal or metal alloy included in the solder.

9. The piezoelectric actuator unit according to claim 1, wherein at least one piezoelectric element is not bonded to another piezoelectric element.

10. A piezoelectric actuator unit comprising:
a first piezoelectric element including an external electrode;
a second piezoelectric element including an external electrode, the second element positioned with the external electrode of the first element positioned apart from the external electrode of the second element; and
a conductive member connected to the external electrodes with a solder, the solder and the soldered portions of the conductive member include indium, bismuth, or a mixture thereof, and the conductive member is configured to transfer stress away from the soldered portions.

11. The piezoelectric actuator unit according to claim 10, wherein at least a part of the conductive member between the soldered portions is capable of changing shape to transfer stress away from the soldered portions.

12. The piezoelectric actuator unit according to claim 11, wherein the conductive member is a braided wire.

13. The piezoelectric actuator unit according to claim 10, wherein the length of the conductive member spanning the soldered portions is greater than the distance between the soldered portions.

14. The piezoelectric actuator unit according to claim 13, wherein at least a part of the conductive member between the soldered portions is curved.

15. The piezoelectric actuator unit according to claim 10, wherein the soldered surfaces of the external electrodes are positioned in coplanar alignment and at least a part of the conductive member between the soldered portions extends away from the plane.

16. The piezoelectric actuator unit according to claim 10, further comprising at least a third piezoelectric element including an external electrode, the conductive member is connected to the external electrode of the third element with a solder, the solder and soldered portions of the conductive member include indium, bismuth, or a mixture thereof, and the conductive member is configured to transfer stress away from the soldered portions.

17. The piezoelectric actuator unit according to claim 10, further comprising a third piezoelectric element including an external electrode, and a second conductive member soldered to the external electrodes of the second and third piezoelectric elements, the solder and soldered portions of the second conductive member include indium, bismuth, or a mixture thereof, and the second conductive member is configured to transfer stress away from the soldered portions.

18. A method of making a piezoelectric actuator unit comprising:
providing a first piezoelectric element including an external electrode, a second piezoelectric element including an external electrode, and a solder including indium, bismuth, or a mixture thereof;
connecting a first part of the conductive member to the external electrode of the first element with the solder and diffusing some of the indium and/or bismuth in the solder into the first part; and
connecting a second part of the conductive member to the external electrode of the second element with the solder and diffusing some of the indium and/or bismuth in the solder into the second part.

19. The method of making a piezoelectric actuator unit according to claim 18, wherein the melting point of the solder provided is 140° C. or lower.

20. The method of making a piezoelectric actuator unit according to claim 18, wherein the solder includes 30.0 to 90.0 percent indium by weight of the solder, 9.0 to 70 percent tin by weight of the solder, 0.1 to 3.0 percent silver by weight of the solder, and up to 0.5 percent copper by weight of the solder.
